(19) United States
(12) Patent Application Publication
(10) Pub. No.: US 2007/0259500 A1
(43) Pub. Date: Nov. 8, 2007

(54) Structure Having Isolation Structure Including Deuterium Within A Substrate And Related Method

(75) Inventors: Kangguo Cheng, Beacon, NY (US); Oh-Jung Kwon, Hopewell Junction, NY (US); Deok-Kee Kim, Bedford Hills, NY (US); James W. Adkisson, Jericho, VT (US)

Correspondence Address: HOFFMAN, WARNICK & D'ALESSANDRO LLC, 75 STATE ST, 14TH FL, ALBANY, NY, 12207, US

(73) Assignee: International Business Machines Corporation, Armonk, NY (US)

(21) Appl. No.: 11/381,861

(22) Filed: May 5, 2006

(51) Int. Cl. H01L 21/336; H01L 21/76; H01L 27/12; H01L 27/01; H01L 31/0392

(52) U.S. Cl. 438/272; 438/424; 257/347

(57) ABSTRACT

Structures having an isolation structure including deuterium and a related method are disclosed. The deuterium is preferably substantially uniformly distributed, and has a concentration (based on total hydrogen atom content) greater than that found in naturally occurring hydrogen. One structure includes a substrate for a semiconductor device including an isolation structure within the substrate, the isolation structure including substantially uniformly distributed deuterium in a concentration (based on total hydrogen atom content) greater than that found in naturally occurring hydrogen. The substrate may include a semiconductor-on-insulator substrate. A method may include the steps of: providing an isolation structure in a substrate, the isolation structure including deuterium; and annealing to diffuse the deuterium into the substrate (prior to and/or after forming a gate dielectric). The structures and method provide a more efficient means for incorporating deuterium and reducing defects. In addition, the deuterium anneal can occur prior to gate dielectric formation during front-end-of-line processes, such that the anneal temperature can be high to improve deuterium incorporation with reduced anneal time.

### BACKGROUND OF THE INVENTION

1. Technical Field

The invention relates generally to semiconductor fabrication, and more particularly, to structures having an isolation structure, such as an isolation structure, within a substrate, the isolation structure including deuterium, and a related method.

2. Background Art

In the semiconductor fabrication industry, deuterium is commonly used to minimize defects in gate dielectrics. Deuterium is an isotope of hydrogen which has one neutron, as opposed to zero neutrons in hydrogen. Deuterium is typically diffused into silicon areas of a substrate that may exhibit defects, e.g., gate dielectrics. One approach to diffuse deuterium into a substrate is to anneal the entire device at the end of the manufacturing process in a deuterium rich environment, e.g., by providing an atmosphere containing deuterium, providing a deuterium rich layer of material over the device or providing a deuterium-rich plasma. This approach is disadvantageous because the anneal temperature is relatively low and it requires an extended time to ensure the deuterium diffuses through the multiple back-end-of-line (BEOL) layers of interconnects over the gate to the gate dielectric. In another approach, a deuterium reservoir is provided within the substrate, which supplies deuterium during a subsequent high temperature anneal. For example, U.S. Pat. No. 6,114,734 discloses deuterium included in a cap layer. A shortcoming of this approach is that during the subsequent high temperature anneal, the deuterium may diffuse out of the substrate. In another approach, as disclosed in U.S. Pat. No. 6,143,634, a high temperature anneal is used before BEOL processing. Unfortunately, deuterium may diffuse away from defect sites in the subsequent high-temperature processes.

In view of the foregoing, there is a need for a solution to the problems of the related art.

### SUMMARY OF THE INVENTION

Structures having an isolation structure including deuterium and a related method are disclosed. The deuterium is substantially uniformly distributed, and has a concentration (based on total hydrogen atom content) greater than that found in naturally occurring hydrogen. One structure includes a substrate for a semiconductor device including an isolation structure within the substrate, the isolation structure including substantially uniformly distributed deuterium in a concentration (based on total hydrogen atom content) greater than that found in naturally occurring hydrogen. The substrate may include a semiconductor-on-insulator substrate. A method may include the steps of: providing an isolation structure in a substrate, the isolation structure including deuterium; and annealing to diffuse the deuterium into the substrate (prior to and/or after forming a gate dielectric). The structures and method provide a more efficient means for incorporating deuterium and reducing defects. In addition, the deuterium anneal can occur prior to gate dielectric formation during front-end-of-line processes, such that the anneal temperature can be high to improve deuterium incorporation with reduced anneal time.

A first aspect of the invention provides a structure comprising: a substrate for a plurality of semiconductor devices including an isolation structure for isolating individual devices from each other within the substrate, the isolation structure including a substantially uniformly distributed deuterium in a concentration greater than naturally occurring hydrogen.

A second aspect of the invention provides a method of incorporating deuterium into a substrate, the method comprising the steps of: providing an isolation structure in a substrate for isolating individual devices from each other, the isolation structure including a substantially uniformly distributed deuterium in a concentration (based on total hydrogen atom content) greater than that found in naturally occurring hydrogen; and annealing to diffuse the deuterium into a defect site in the substrate.

A third aspect of the invention is directed to a structure comprising: a semiconductor-on-insulator (SOI) substrate including an SOI layer over a buried insulator layer over a substrate layer, the buried insulator layer including deuterium; and an isolation structure in the SOI layer, the isolation structure including a substantially uniformly distributed deuterium in a concentration (based on total hydrogen atom content) greater than that found in naturally occurring hydrogen.

A fourth aspect of the invention provides a structure comprising: a semiconductor-on-insulator (SOI) substrate including an SOI layer over a buried insulator layer over a substrate layer; and a contact to the SOI layer, the contact including a substantially uniformly distributed deuterium in a concentration (based on total hydrogen atom content) greater than that found in naturally occurring hydrogen.

A fifth aspect of the invention provides a structure comprising: a semiconductor-on-insulator (SOI) substrate including an SOI layer over a buried insulator layer over a substrate layer; a contact to the substrate layer, the contact including a substantially uniformly distributed deuterium in a concentration (based on total hydrogen atom content) greater than that found in naturally occurring hydrogen.

The illustrative aspects of the present invention are designed to solve the problems herein described and/or other problems not discussed.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a first embodiment of a structure according to the invention.

FIG. 2 shows a second embodiment of a structure according to the invention.

FIG. 3 shows details of a trench isolation according to one embodiment of the invention.

FIGS. 4-5 show one embodiment of a method of incorporating deuterium into a substrate using the structure of FIG. 1.

FIGS. 6-8 show one embodiment of a method of incorporating deuterium into a substrate using the structure of FIG. 2.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

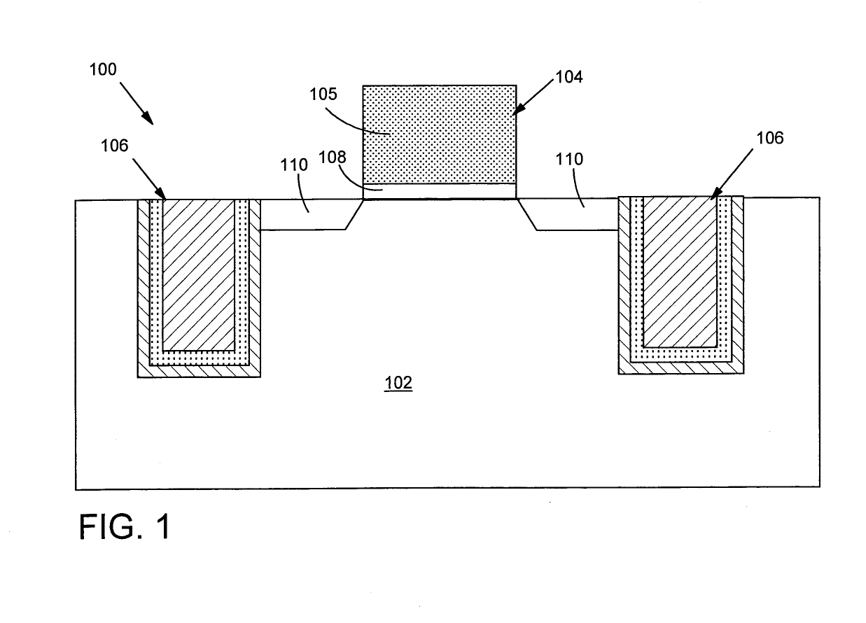

Referring to the drawings, FIG. 1 shows one embodiment of a structure 100 according to the invention. Structure 100 includes a substrate 102 for a semiconductor device 104 including an isolation structure 106 (two shown) within substrate 102 for isolating semiconductor device 104 from other devices (not shown), each isolation structure 106 includes deuterium.

The deuterium in isolation structure 106 is preferably substantially uniformly distributed deuterium, i.e., it is not simply diffused into an upper surface thereof. In addition, the deuterium is provided in a concentration greater than that found in naturally occurring hydrogen, i.e., greater than 0.02% (based on total hydrogen atom content), and, in one embodiment, in a concentration substantially greater than that found in naturally occurring hydrogen. As used herein, “including deuterium” means including a concentration (based on total hydrogen atom content) of deuterium greater than that found in naturally occurring hydrogen, and typically, a concentration substantially greater than that found in naturally occurring hydrogen.

Isolation structure 106 may take the physical form of any now known or later developed isolation structure, including but not limited to, shallow trench isolation (STI) structures, deep trench isolation (DTI) structures, local oxidation isolation (LOCOS), etc. Since isolation structure 106 includes deuterium, it may provide a deuterium reservoir that is available prior to gate dielectric 108 formation, as will be described below. Deuterium from such a reservoir may be diffused to defect-containing areas of substrate 102 to passivate defects in those areas. Accordingly, a deuterium anneal to promote diffusion of the deuterium into defect sites in substrate 102 (i.e., a substrate 102 as used herein may include defect sites such as at the interface between gate dielectric 108 and substrate 102) may be conducted prior to and/or after gate dielectric 108 formation during front-end-of-line (FEOL) processes, such that an anneal temperature can be high and the anneal time can be minimized. Isolation structure 106 also provides a shorter diffusion path for deuterium to areas such as gate dielectric 108 or isolation structure 106 interfaces within substrate 102 that may exhibit defects.

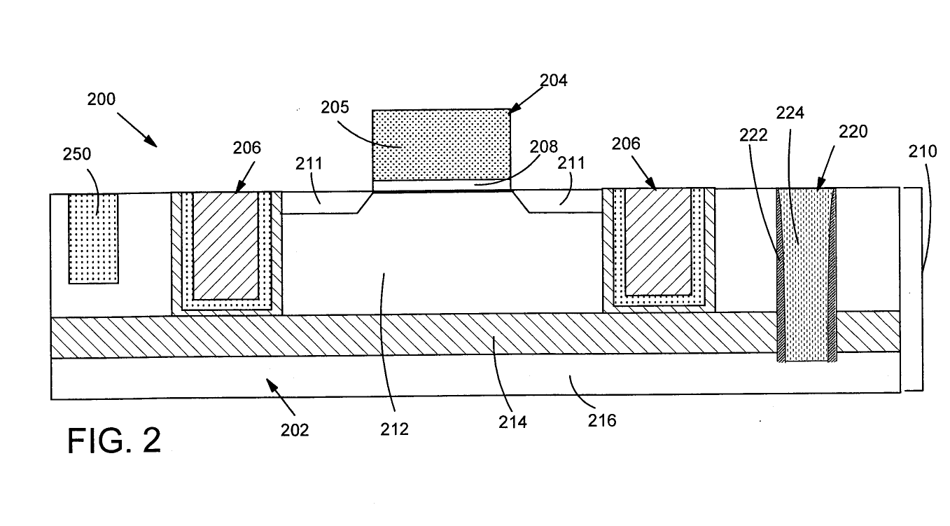

FIG. 2 shows an alternative embodiment of a structure 200 according to the invention. Structure 200 includes a substrate 202 for a semiconductor device 204 including an isolation structure 206 (two shown) for isolating semiconductor device 204 from other devices (not shown), each isolation structure 206 including a substantially uniformly distributed deuterium in a concentration (based on total hydrogen atom content) greater than that found in naturally occurring hydrogen. In contrast to FIG. 1, however, in this embodiment, substrate 202 is provided in the form of a semiconductor-on-insulator (SOI) substrate 210 including an SOI layer 212, a buried insulator layer 214, and a substrate layer 216. SOI layer 212, may include, but is not limited to, silicon (Si), germanium (Ge), silicon germanium (SiGe), silicon carbide (SiC), and those materials consisting essentially of one or more compound semiconductors such as gallium arsenic (GaAs), gallium nitride (GaN), and indium phosphoride (InP). Buried insulator layer 214 may include, but is not limited to, silicon oxide, silicon nitride, silicon oxynitride, and other dielectric materials such as “high-k” dielectric materials (e.g., hafnium oxide, zirconium oxide, hafnium silicate, etc.). Substrate layer 216 may include any suitable semiconductor material such as silicon (Si), germanium (Ge), silicon germanium (SiGe), silicon carbide (SiC), polysilicon, and those consisting essentially of one or more compound semiconductors such as gallium arsenic (GaAs), gallium nitride (GaN), and indium phosphoride (InP). SOI layer 212 and substrate layer 216 may have the same or different materials. Isolation structures 206 are substantially identical to that shown in FIG. 1, except they extend to buried insulator layer 214. In one embodiment, buried insulator layer 214 may also include deuterium so as to act as a further deuterium reservoir.

FIG. 2 also shows an alternative embodiment including a contact 220 to silicon substrate layer 216. Contact 220 may include an insulating spacer 222, e.g., of silicon nitride (Si₃N₄), and a conductor material 224, e.g., polysilicon. In one embodiment, conductor material 224 may also include deuterium. Furthermore, insulating spacer 222 may also include deuterium. Another alternative, shown in FIG. 2, includes a contact or plug 250 including deuterium, to SOI layer 212.

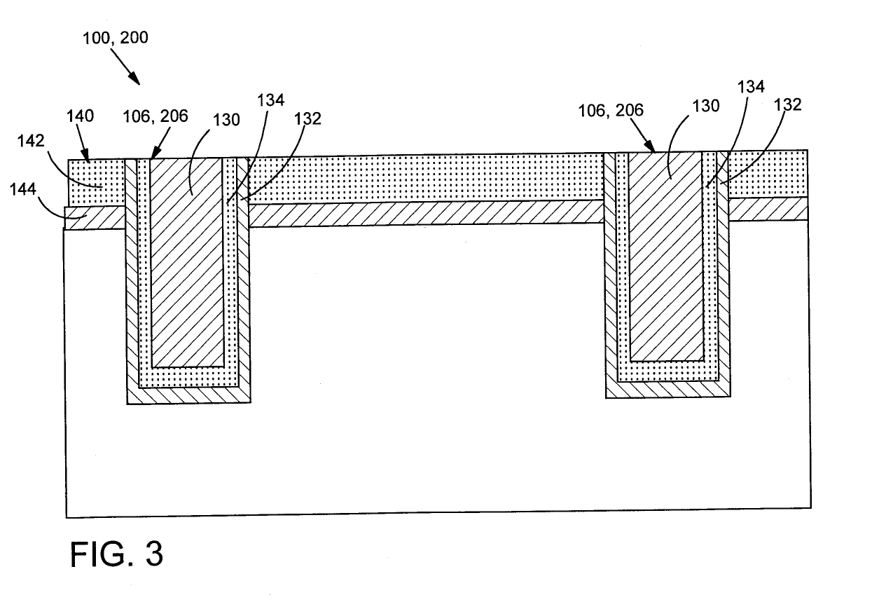

Turning to FIG. 3, details of isolation structures 106, 206 will now be described. In one embodiment, isolation structures 106, 206 are trench isolations and each trench isolation 106, 206 includes a fill material 130 such as silicon oxide or any other fill material now known or later developed for use in trench isolations. However, fill material 130 includes a substantially uniformly distributed deuterium in a concentration (based on total hydrogen atom content) greater than that found in naturally occurring hydrogen. In one embodiment, isolation structures 106, 206 may also include a silicon oxide liner 132 including deuterium and/or a silicon nitride (Si₃N₄) liner 134 including deuterium, each of which provide a further deuterium reservoir. As shown in FIG. 3, in one embodiment, structures 100, 200 may further include a pad layer 140 adjacent to isolation structure 106, 206. Pad layer 140 may also include deuterium. In one embodiment, pad layer 140 includes a silicon nitride (Si₃N₄) layer 142 and a silicon oxide layer 144, each of which may include deuterium.

In an alternative embodiment, isolation structures 106, 206 are formed by local oxidation isolation (LOCOS). In this case, insulating material 130 may include silicon oxide formed by thermal oxidation. Deuterium is incorporated into insulating material 130 by using deuterated species, such as deuterium gas (D₂), heavy water (D₂O), and/or deuterated ammonia (ND₃) in the oxidation process. Alternatively, deuterium incorporation is achieved after forming insulating material 130 by performing ion implantation, gas phase doping, plasma doping, plasma immersion ion implantation, infusion doping, liquid phase doping, solid phase doping, etc.

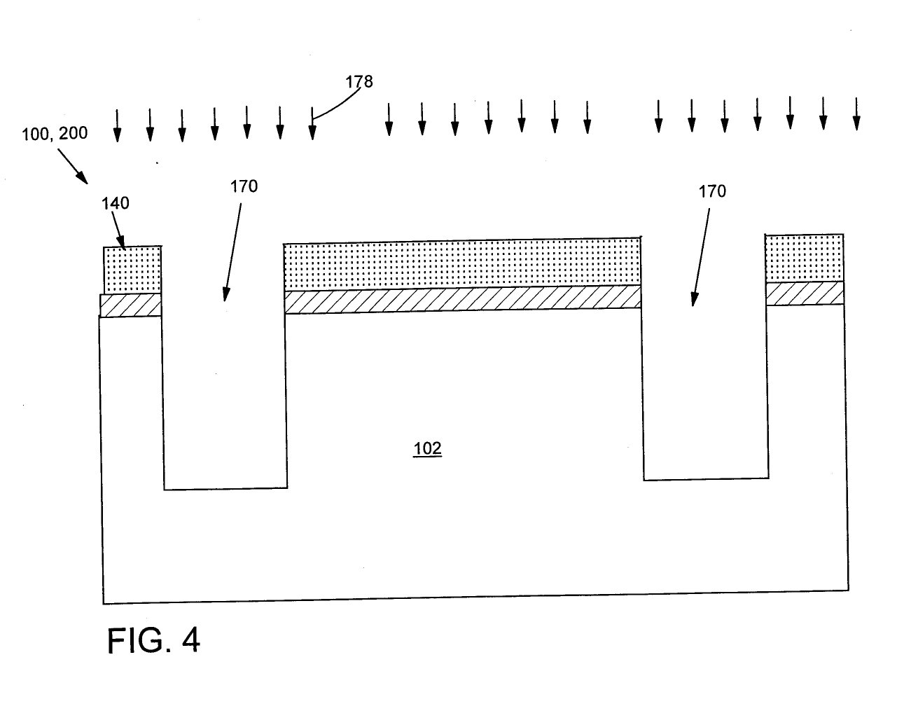

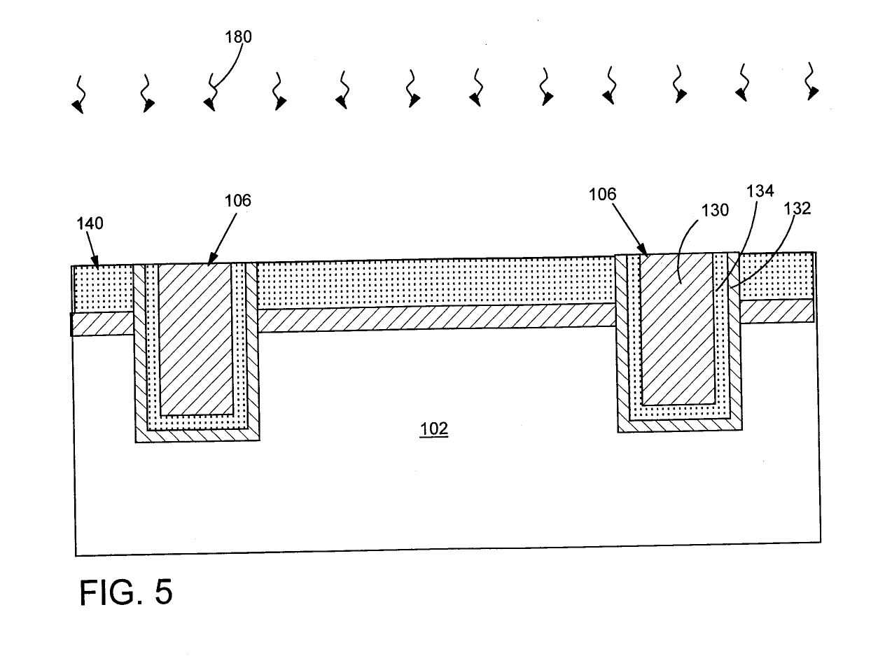

Turning to FIGS. 4-5, one embodiment of a method of incorporating deuterium into the substrate using isolation structure 106 (FIG. 1) according to the invention will now be described. In a first step, shown in FIG. 4, trench isolation opening 170 is formed in substrate 102 and through pad layer 140, e.g., by any appropriate etching 178. Pad layer 140 may be provided, as described above, and may be formed using any conventional processing. Next, as shown in FIG. 5, isolation structure 106 is provided (formed) including a substantially uniformly distributed deuterium in a concentration (based on total hydrogen atom content) greater than that found in naturally occurring hydrogen. In one embodiment, this step may include forming silicon oxide layer 132 and/or silicon nitride layer 134, at least one of layers 132 and 134 including deuterium. Fill material 130 including, for example, silicon oxide and including deuterium may be formed and then planarized. In one embodiment, parts 130 and 132 are formed by thermal oxidation and thermal nitridation, respectively, by using deuterated species, such as deuterium gas (D₂), heavy water (D₂O), and/or deuterated ammonia (ND₃) in the thermal oxidation or nitridation process for deuterium incorporation. In another embodiment, parts 130 and 132 are formed by any suitable deposition technique such as chemical vapor deposition (CVD), low-pressure CVD (LPCVD), plasma-enhanced CVD (PECVD), semi-atmosphere CVD (SACVD), high density plasma CVD (HDPCVD) using deuterated deposition precursors such as deuterated tetra-ethyl-ortho-silicate (TEOS). In another embodiment, part 130 is formed by using deuterated spin-on-glass. In another embodiment, deuterium is incorporated into parts 130, 132, and/or 134 after forming these parts by performing ion implantation, gas phase doping, plasma doping, plasma immersion ion implantation, infusion doping, liquid phase doping, solid phase doping, etc. In any of the embodiments employed, the result is a substantially uniformly distributed deuterium in a concentration (based on total hydrogen atom content) greater than that found in naturally occurring hydrogen.

Next, as also shown in FIG. 5, an anneal 180 is performed to diffuse the deuterium into substrate 102 (i.e., defect sites in substrate 102) prior to or after forming gate dielectric 108 (FIG. 1). In one embodiment, anneal 180 may occur at a temperature of greater than approximately 800° C. In another embodiment, anneal 180 may occur at a temperature of less than approximately 800° C. but greater than approximately 350° C. Returning to FIG. 1, subsequent processing may include standard techniques to strip pad layer 140 (FIG. 5) and form semiconductor device 104 including gate conductor 105, gate dielectric 108 and source/drain regions 110. During these steps, deuterium is constantly incorporated into the defect sites such as the interface between gate dielectric 108 and substrate 102 from isolation structures 106.

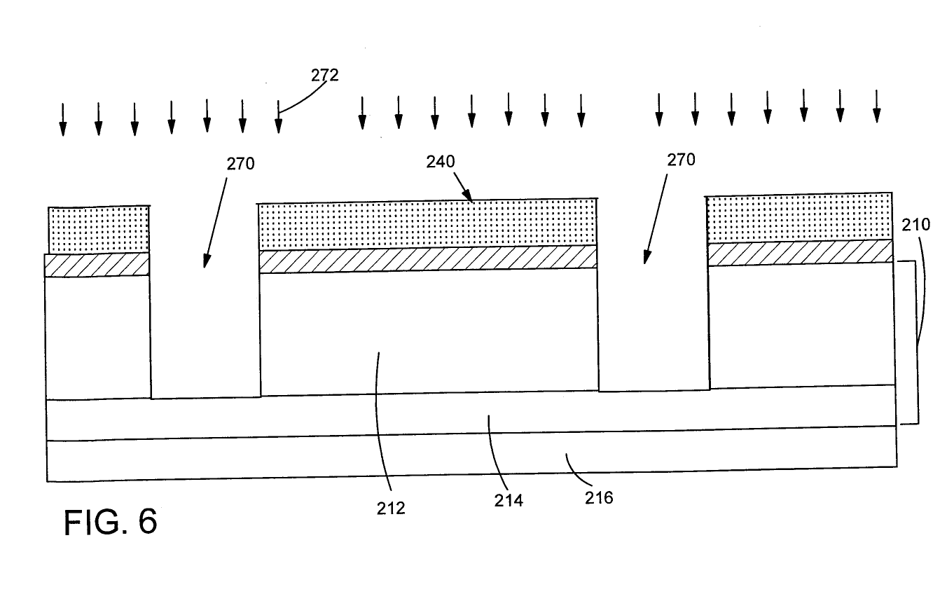

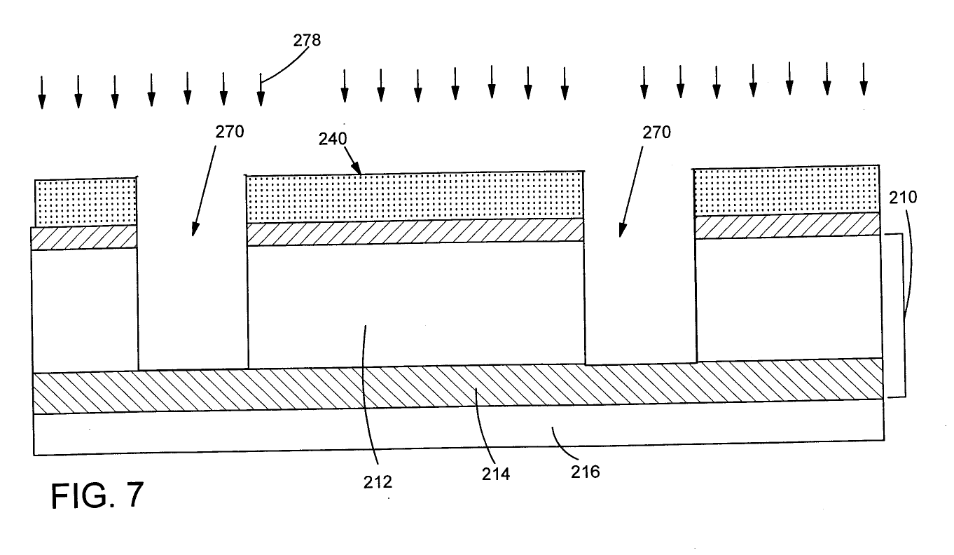

FIGS. 6-8 illustrate one embodiment of a method of incorporating deuterium using isolation structure 206 (FIG. 2) according to the invention. In this embodiment, SOI substrate 210 is provided including a trench isolation opening 270 through a pad layer 240 to a buried insulator layer 214, e.g., silicon oxide. Opening 270 may be formed using any conventional patterning and etching process 272. Next, as shown in FIG. 7, process 278 in which deuterium may be incorporated into buried insulator layer 214 is performed by, for example, ion implantation, gas phase doping, plasma doping, plasma immersion ion implantation, infusion doping, liquid phase doping, solid phase doping, etc.

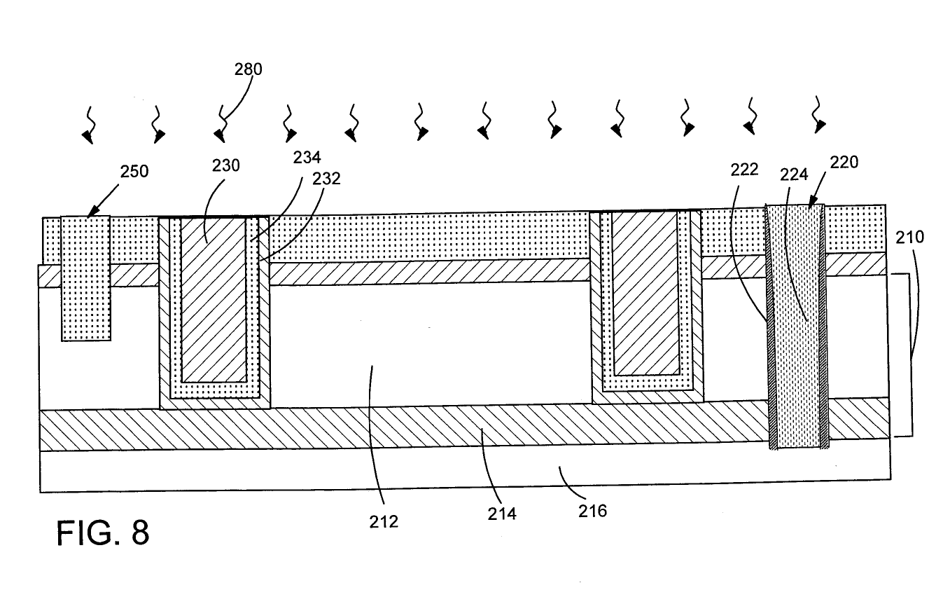

Next, as shown in FIG. 8, trench isolation opening 270 (FIG. 7) is then filled. In one embodiment, this step may include forming silicon oxide liner 232 and/or silicon nitride liner 234, at least one of liners 232 and 234 including deuterium. Fill material 230 including, for example, silicon oxide, and including deuterium may then be formed and then planarized. In one embodiment, parts 230 and 232 are formed by thermal oxidation and thermal nitridation, respectively, by using deuterated species, such as deuterium gas (D₂), heavy water (D₂O), and/or deuterated ammonia (ND₃) in the thermal oxidation or nitridation process for deuterium incorporation. In another embodiment, parts 230 and 232 are formed by any suitable deposition technique such as chemical vapor deposition (CVD), low-pressure CVD (LPCVD), plasma-enhanced CVD (PECVD), semi-atmosphere CVD (SACVD), high density plasma CVD (HDPCVD) using deuterated deposition precursors such as deuterated tetra-ethyl-ortho-silicate (TEOS). In another embodiment, part 230 is formed by using deuterated spin-on-glass. In another embodiment, deuterium is incorporated into parts 230, 232, and/or 234 after forming these parts by performing ion implantation, gas phase doping, plasma doping, plasma immersion ion implantation, infusion doping, liquid phase doping, solid phase doping, etc. Again, in any of the embodiments, the deuterium is substantially uniformly distributed in a concentration (based on total hydrogen atom content) greater than that found in naturally occurring hydrogen.

In addition, as also shown in FIG. 8, contact 220 to silicon substrate layer 216 including insulating spacer 222 and conductor material 224 including deuterium may be formed by using any now known or later developed processing. In addition, contact 250 including deuterium to SOI layer 212 may be formed by using any now known or later developed processing.

Furthermore, as shown in FIG. 8, an anneal 280 to diffuse the deuterium into defect sites prior to or after forming gate dielectric 208 (FIG. 2) may be performed. In one embodiment, anneal 280 may occur at a temperature of greater than approximately 800° C. In another embodiment, anneal 280 may occur at a temperature of less than approximately 800° C. but greater than approximately 350° C.

Returning to FIG. 2, subsequent processing may include standard techniques to strip pad layer 240 (FIG. 8) and form semiconductor device 204 including gate conductor 205, gate dielectric 208 and source/drain regions 211. During these steps, deuterium is constantly incorporated into substrate 210, i.e., the defect sites of substrate 210 such as the interface between gate dielectric 208 and substrate 212 from isolation structures 206, buried insulator layer 214 and contacts 220, 250.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A structure comprising:
a substrate for a plurality of semiconductor devices including an isolation structure for isolating individual devices from each other within the substrate, the isolation structure including a substantially uniformly distributed deuterium in a concentration (based on total hydrogen atom content) greater than that found in naturally occurring hydrogen.

2. The structure of claim 1, wherein the isolation structure includes a local oxidation isolation.

3. The structure of claim 1, wherein the isolation structure includes a trench isolation.

4. The structure of claim 3, wherein the trench isolation includes a fill material including deuterium and at least one of: a silicon oxide liner including deuterium and a silicon nitride liner including deuterium.

5. The structure of claim 4, wherein the fill material includes silicon oxide.

6. The structure of claim 1, wherein the substrate includes a silicon-on-insulator (SOI) layer over a buried insulator layer over a silicon layer, the buried insulator layer including deuterium.

7. The structure of claim 6, further comprising a contact to the silicon layer, the contact including an insulating spacer including deuterium and a conductor material including deuterium.

8. The structure of claim 6, further comprising a contact to the SOI layer, the contact including deuterium.

9. The structure of claim 1, further comprising a pad layer adjacent to the isolation structure, the pad layer including deuterium.

10. The structure of claim 9, wherein the pad layer includes a silicon nitride layer and a silicon oxide layer.

11. A method of incorporating deuterium into a substrate, the method comprising the steps of:
providing an isolation structure in a substrate for isolating individual devices from each other, the isolation structure including a substantially uniformly distributed deuterium in a concentration (based on total hydrogen atom content) greater than that found in naturally occurring hydrogen; and
annealing to diffuse the deuterium into a defect site in the substrate.

12. The method of claim 11, further comprising providing a pad layer adjacent to the isolation structure, the pad layer including deuterium.

13. The method of claim 11, wherein the isolation structure is provided by etching an isolation trench and filling the isolation trench with a fill material including deuterium.

14. The method of claim 13, wherein the isolation structure is further provided by forming at least one of a silicon oxide liner including deuterium and a silicon nitride liner including deuterium in the isolation trench prior to filling the isolation trench with the fill material.

15. The method of claim 11, wherein the substrate includes a silicon-on-insulator (SOI) layer over a buried insulator layer over a silicon layer, further comprising forming a contact to the silicon layer, the contact including an insulating spacer including deuterium and a conductor material including deuterium.

16. The method of claim 15, further comprising forming a contact to the SOI layer, the contact including deuterium.

17. A structure comprising:
a semiconductor-on-insulator (SOI) substrate including an SOI layer over a buried insulator layer over a substrate layer, the buried insulator layer including deuterium; and
an isolation structure in the SOI layer, the isolation structure including a substantially uniformly distributed deuterium in a concentration (based on total hydrogen atom content) greater than that found in naturally occurring hydrogen.

18. The structure of claim 17, wherein the isolation structure includes a fill material including deuterium and at least one of: a silicon oxide liner including deuterium and a silicon nitride liner including deuterium.

19. The structure of claim 17, further comprising a contact to the substrate layer, the contact including an insulating spacer including deuterium and a conductor material including deuterium.

20. The structure of claim 17, further comprising a contact to the SOI layer, the contact including deuterium.
